(19) United States
(12) Patent Application Publication
(10) Pub. No.: US 2026/0343751 A1
(43) Pub. Date: Oct. 29, 2026

(54) COMPONENT EMBEDDED SUBSTRATE MANUFACTURING METHOD AND COMPONENT EMBEDDED SUBSTRATE

(71) Applicant: SHINKO ELECTRIC INDUSTRIES CO., LTD., Nagano-shi (JP)

(72) Inventor: Takaaki Imai, Nagano (JP)

(21) Appl. No.: 19/657,279

(22) Filed: Apr. 24, 2026

(30) Foreign Application Priority Data
Apr. 28, 2025 (JP) 2025-074181

(51) Int. Cl. H05K 1/185; H05K 1/11; H05K 3/38

(52) U.S. Cl. CPC H05K 1/188; H05K 1/115; H05K 3/38; H05K 2201/10015

(57) ABSTRACT

An component embedded substrate manufacturing method includes a process of forming a build-up layer that contains filler and includes a first insulating resin layer including a first surface and a second surface located opposite to the first surface, and includes a wiring layer, a process of forming a cavity by cutting the build-up layer to the one surface of the wiring layer, a process of disposing an electrical component on one surface of the wiring layer in the cavity, a process of forming, on the first surface, a filler-rich layer that is configured such that an occupancy rate of filler in the first surface is higher than an occupancy rate of filler in the second surface, by plasma treatment, a process of forming a second insulating resin layer that is injected in the cavity and convers the first insulating resin layer and the electrical component, and a process of forming a via that penetrates through the second insulating resin layer and the first insulating resin layer and that has a bottom surface formed of one surface of a different wiring layer of the build-up layer from one surface of the wiring layer in the cavity.

### CROSS-REFERENCE TO RELATED APPLICATION

This application is based upon and claims the benefit of priority of the prior Japanese Patent Application No. 2025-074181, filed on Apr. 28, 2025, the entire contents of which are incorporated herein by reference.

### FIELD

The embodiment discussed herein is related to a component embedded substrate manufacturing method and a component embedded substrate.

### BACKGROUND

A build-up printed circuit board is manufactured by using a build-up method. For example, Patent Literature 1 discloses, as an inter-layer insulating layer of multilayer wiring, a build-up printed circuit board in which a second insulating layer is laminated on a first insulating layer that is formed by using the build-up method such that the second insulating layer covers an upper surface and side surfaces of a wiring layer.

With regard to the build-up printed circuit board, to realize high-density component mounting, for example, a component embedded substrate that is configured such that a component, such as a condenser, is incorporated in the substrate is attracting attention. The component embedded substrate is manufactured by, for example, arranging a cavity in a substrate in which a build-up layer including a first insulating resin layer and a wiring layer is formed, disposing a component in the cavity, and laminating, on the first insulating resin layer, a second insulating resin layer that is injected in the cavity.

Patent Literature 1: Japanese Laid-open Patent Publication No. 2024-067275

Patent Literature 2: Japanese Laid-open Patent Publication No. 2024-061022

Meanwhile, due to recent design requirements, a material in which the content of SiO₂ (hereinafter, referred to as filler) exceeds, for example, 70 wt% is used as a material with a low thermal expansion coefficient and low loss, and therefore, melt viscosity of insulating resin that is used for manufacturing a component embedded substrate is low. Therefore, fluidity of the insulating resin is low and adhesion between the insulating resin may become insufficient.

Further, in some cases, a process that may affect adhesion between the first insulating resin layer and the second insulating resin layer may be performed before injecting the second insulating resin layer in the cavity in which a component is disposed, and the process may cause insufficient adhesion between the insulating resin. For example, in some cases, before injecting second insulating resin in the cavity, chemical treatment for improving adhesion between the component in the cavity and the second insulating resin or thermal treatment for fixing the component in the cavity may be performed. In this case, due to the influence of a chemical solution or heat, a functional group that affects adhesion of the first insulating resin layer may disappear or roughness of the first insulating resin layer may be reduced. As a result, the first insulating resin layer and the second insulating resin layer are easily delaminated from each other due to poor adhesion, plating is deposited between the delaminated resin in a subsequent plating wiring process, and a plating layer is formed, so that a short circuit may occur between adjacent wires.

### SUMMARY

According to an aspect of an embodiment, an component embedded substrate manufacturing process includes
forming a build-up layer that contains filler and includes a first insulating resin layer, the first insulating layer including a first surface and a second surface located opposite to the first surface, and a wiring layer;
forming a cavity by cutting the build-up layer to one surface of the wiring layer;
disposing an electrical component on the one surface of the wiring layer in the cavity;
forming, on the first surface, a filler-rich layer that is configured such that an occupancy rate of filler in the first surface is higher than an occupancy rate of filler in the second surface, by plasma treatment;
forming a second insulating resin layer that is injected in the cavity and convers the first insulating resin layer and the electrical component; and
forming a via that penetrates through the second insulating resin layer and the first insulating resin layer and that has a bottom surface formed of one surface of a different wiring layer of the build-up layer from the one surface of the wiring layer in the cavity.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a component embedded substrate according to an embodiment;

FIG. 2 is a flow diagram illustrating a component embedded substrate manufacturing method according to the embodiment;

FIG. 3 is a diagram illustrating a specific example of a build-up process;

FIG. 4 is a diagram illustrating a specific example of a cavity formation process;

FIG. 5 is a diagram illustrating a specific example of a component mounting process;

FIG. 6 is a diagram illustrating a specific example of a plasma treatment process;

FIG. 7 is a diagram illustrating a specific example of a component embedding process;

FIG. 8 is a diagram illustrating a specific example of a laser via processing process;

FIG. 9 is a diagram illustrating a specific example of a wiring formation process;

FIG. 10 is a diagram illustrating a specific example of a solder resist formation process;

FIG. 11 is a diagram illustrating an example of an interlayer between insulating resin layers according to a reference example;

FIG. 12 is a diagram illustrating an example of an interlayer between insulating resin layers according to the embodiment;

FIG. 13 is a diagram illustrating another specific example of the component embedding process; and

FIG. 14 is a diagram illustrating an example of an interlayer between insulating resin layers in the other specific example of the component embedding process.

### DESCRIPTION OF EMBODIMENT

An embodiment of a component embedded substrate manufacturing method and a component embedded substrate will be described in detail below with reference to the drawings. Note that the embodiment does not limit the disclosed technique.

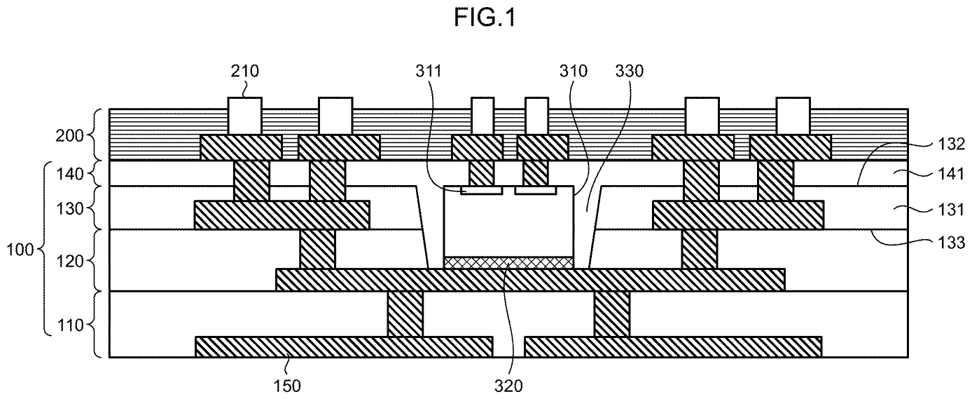

FIG. 1 is a diagram illustrating a configuration of a component embedded substrate according to one embodiment. In FIG. 1, a cross section of the component embedded substrate is schematically illustrated. The component embedded substrate has a laminated structure, and mainly includes a build-up layer 100 and a solder resist layer 200. A component 310 is embedded in the build-up layer 100. The build-up layer 100 is divided into a first layer 110, a second layer 120, a third layer 130, and a fourth layer 140. In the following, as illustrated in FIG. 1, explanation will be given based on the assumption that the first layer 110 serves as the lowermost layer and the solder resist layer 200 serves as the topmost layer, but the component embedded substrate may be used upside down or may be used in an arbitrary posture, for example. The first layer 110, the second layer 120, and the third layer 130 include wiring layers 150 such that the adjacent wiring layers 150 are connected to each other by vias.

The first layer 110 includes an insulating build-up resin layer and the wiring layer 150. Build-up resin that forms the first layer 110 is cured by thermal curing and holds the wiring layer 150 inside the first layer 110 at a predetermined position.

The second layer 120 is laminated in an adjacent manner on the first layer 110 and is formed of an insulating build-up resin layer and the wiring layer 150. Build-up resin that forms the second layer 120 is cured by thermal curing and holds the wiring layer 150 inside the second layer 120 at a predetermined position. The wiring layer 150 inside the second layer 120 is connected to the wiring layer 150 inside the first layer 110 by vias.

The third layer 130 is laminated in an adjacent manner on the second layer 120 and is formed of an insulating build-up resin layer and the wiring layer 150. Build-up resin that forms the third layer 130 is cured by thermal curing and holds the wiring layer 150 inside the third layer 130 at a predetermined position. The wiring layer 150 inside the third layer 130 is connected to the wiring layer 150 inside the second layer 120 by vias. A cavity is formed in the second layer 120 and the third layer 130, and the component 310 is embedded in the cavity.

The fourth layer 140 is a resin layer that is formed such that resin injected in the cavity (hereinafter, referred to as filling resin 330) is continuously laminated in an adjacent manner on the third layer 130. Wiring is performed on a surface of the fourth layer 140, and the wiring is covered by the solder resist layer 200. On the fourth layer 140, vias are formed after a component embedding process, and the wiring layer 150 inside the third layer 130 or an electrode pad 311 of the component 310 is connected to the wiring on the surface of the fourth layer 140. The resin layer that forms the fourth layer 140 may be made of the same resin as the build-up resin layers of the first layer 110 to the third layer 130. In the following, the build-up resin layer of the third layer 130 may also be referred to as a “first insulating resin layer 131”, and the resin layer that forms the fourth layer 140 may also be referred to as a “second insulating resin layer 141”.

The wiring layers 150 are made of metal, such as copper, and held at predetermined positions by the build-up resin layers in the respective layers. The wiring layers 150 in the adjacent layers are connected via the vias that are formed in the respective layers, and are electrically conductible. Further, on the wiring layer 150 inside the second layer 120, the component 310 is bonded by an adhesive material 320.

The solder resist layer 200 is a layer that covers wiring arranged on a surface of the build-up layer 100 and protects the wiring. The solder resist layer 200 is formed by, for example, film formation by pattern printing or the like. For example, in a portion in which an external component, such as a semiconductor chip, is mounted, openings are arranged in the solder resist layer 200 and bumps 210 connected to the wiring on the surface of the build-up layer 100 are formed.

The component 310 is, for example, an electronic component, such as a condenser, and also called die. The component 310 is embedded in the second layer 120 and the third layer 130. Specifically, the component 310 is embedded in the build-up layer 100 by injecting the filling resin 330 around the component 310. A lower surface of the component 310 is a bonding surface that is bonded to the wiring layer 150 of the second layer 120 by the adhesive material 320. The component 310 has a rectangular prism shape, for example. However, the shape of the component 310 is not limited to the rectangular prism shape.

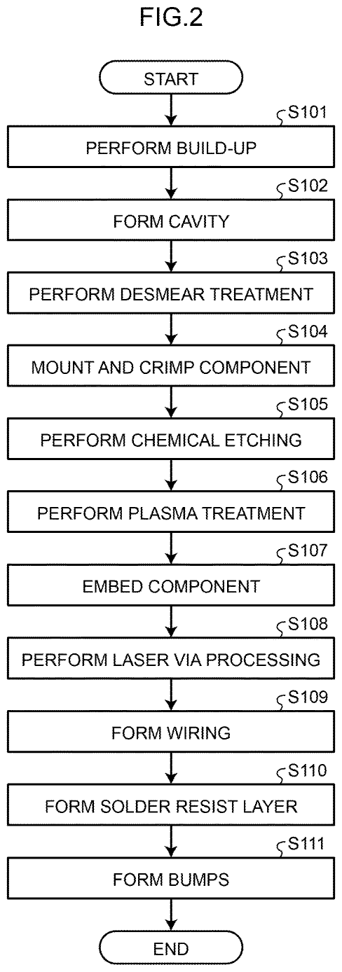

A method of manufacturing the component embedded substrate that is configured as described above will be described below with specific examples, with reference to FIG. 2. FIG. 2 is a flow diagram illustrating a component embedded substrate manufacturing method according to one embodiment.

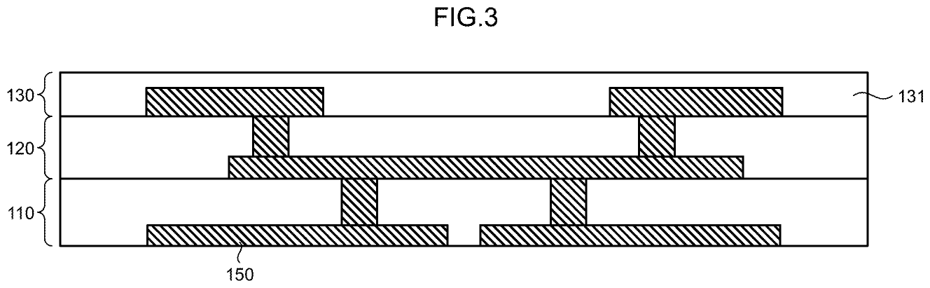

Firstly, in a build-up process, the first layer 110 to the third layer 130 of the build-up layer 100 are laminated (Step S101). Specifically, as illustrated in FIG. 3 for example, the first layer 110 to the third layer 130 each holding the wiring layer 150 are laminated on the build-up resin layers, and the wiring layers 150 between the layers are connected by the vias. At this time, the wiring layer 150 is not arranged in a region in which the component 310 is to be incorporated. In the example illustrated in FIG. 3, the component 310 is to be incorporated in the vicinity of the center of the second layer 120 and the third layer 130, and therefore, the wiring layer 150 is not arranged in this region.

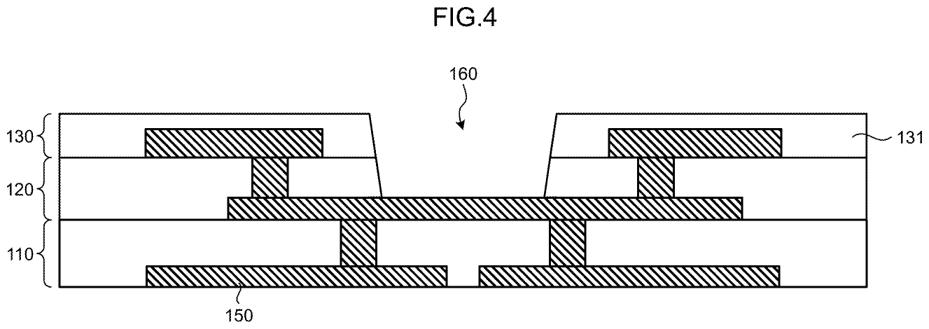

Further, in the region in which the component 310 is to be incorporated, a cavity is formed by cutting the build-up layer 100 to one surface of the wiring layer 150 (Step S102). Specifically, as illustrated in FIG. 4 for example, a cavity 160 is formed by cutting the build-up resin layer (the first insulating resin layer 131) of the second layer 120 and the third layer 130. A cavity formation process may be implemented by, for example, performing counterboring on the build-up resin layers by using CO₂ laser. The wiring layer 150 of the second layer 120 is exposed from a bottom surface of the cavity 160. For example, the cavity 160 has an inverted truncated cone shape with a size in which, for example, the component 310 is housed, and therefore, has a largest diameter on a surface of the third layer 130 and a smallest diameter on the bottom surface of the cavity 160. However, the cavity 160 may have a rectangular prism shape. A rectangular of the bottom surface of the cavity 160 is larger than a rectangular of the bottom surface of the component 310.

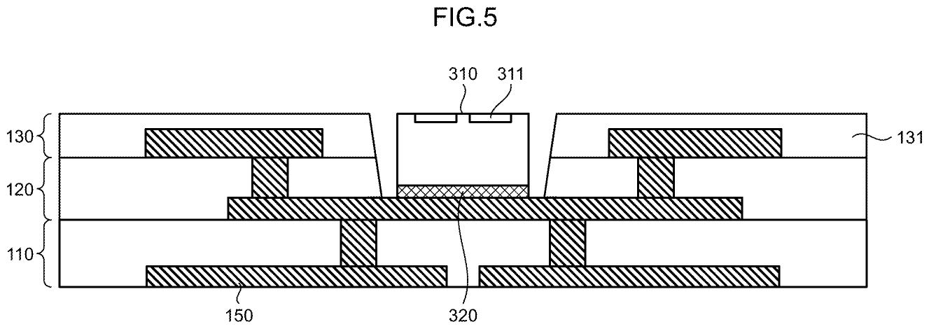

Furthermore, desmear treatment is performed (Step S103). In the desmear treatment, a residue of the build-up resin layers generated at the time of cavity processing is removed. Moreover, the component 310 is mounted in the cavity 160 (Step S104). Specifically, as illustrated in FIG. 5 for example, the component 310 is disposed on the wiring layer 150 in the cavity 160 via the adhesive material 320, and the adhesive material 320 is thermally cured while the component 310 is pressed, so that the component 310 is crimped.

Then, chemical etching is performed (Step S105). The chemical etching is performed by wet etching using a chemical solution in order to improve adhesion between the electrode pad 311 on the component 310 and the filling resin 330 (the second insulating resin layer 141) that is used in the component embedding process (to be described later). As the chemical solution, for example, adhesion promotor (silane coupling agent or the like) that enhances adhesion between the electrode pad 311 and the second insulating resin layer 141 may be used. Meanwhile, the electrode pad is made of, for example, copper.

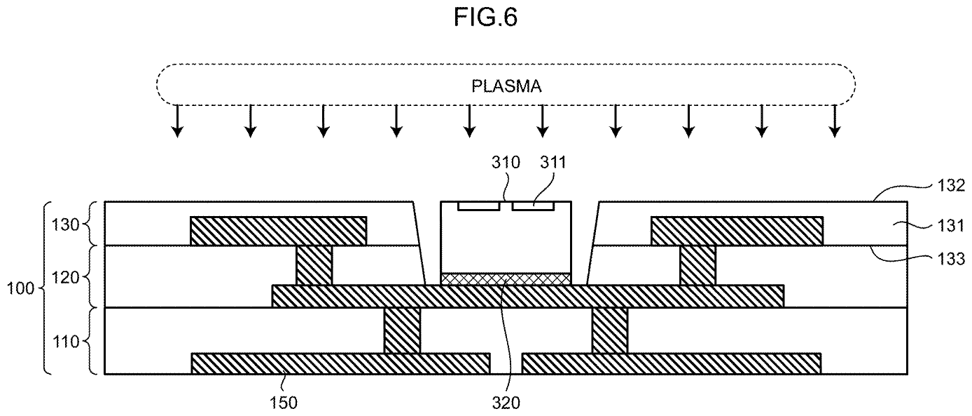

Furthermore, with use of plasma, a plasma treatment process for forming a filler-rich layer on a surface of the first insulating resin layer 131 of the third layer 130 is performed (Step S106). Specifically, as illustrated in FIG. 6 for example, the third layer 130 includes the first insulating resin layer 131 that contains filler and the wiring layer 150. The first insulating resin layer 131 includes a first surface 132 that is a surface of the first insulating resin layer 131 and that is exposed to plasma in the plasma treatment process and a second surface 133 that is located opposite to the first surface 132 and that is not exposed to plasma. In the plasma treatment, plasma is generated from a gas containing a CF₄ gas, and plasma ashing is performed on the first insulating resin layer 131 by using the generated plasma. Accordingly, the filler-rich layer, in which an occupancy rate of filler in the first surface 132 is higher than an occupancy rate of filler in the second surface 133, is formed on the first surface 132. The filler-rich layer may be formed on side surfaces of the second layer 120 the third layer 130 that serve as side surfaces of the cavity 160. As the gas that is used for the plasma treatment process, a CF₄ gas may be used. However, the gas that is used for the plasma treatment process is not limited to the CF₄ gas, but may be a gas that contains carbon and fluorine. For example, as the gas that contains carbon and fluorine, CₓF_{y} (x=1 to 5, y=4 to 12: PFC gas (perfluorocarbon)) may be used. Moreover, the gas that is used for the plasma treatment process may contain oxygen in addition to carbon and fluorine.

Meanwhile, order of the chemical etching process (Step S105) and the plasma treatment process (Step S106) as described above is interchangeable. Specifically, it may be possible to first form the filler-rich layer on the surface of the first insulating resin layer 131 of the third layer 130 with use of plasma, and thereafter perform wet etching using a chemical solution.

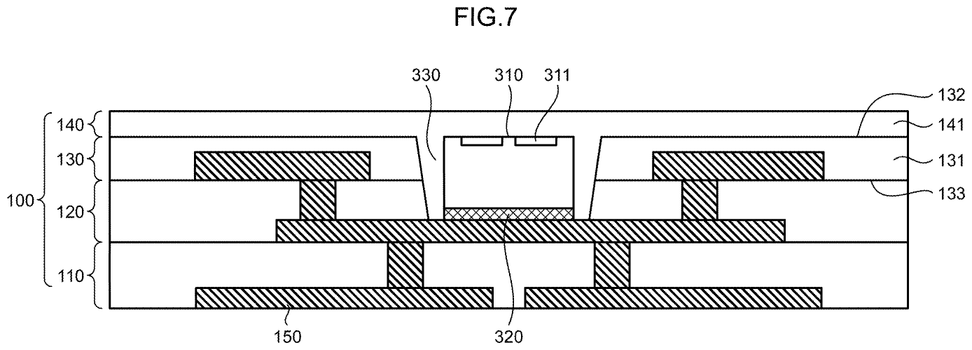

Furthermore, in the component embedding process, the fourth layer 140 is laminated on the third layer 130, so that the component 310 is embedded (Step S107). Specifically, as illustrated in FIG. 7 for example, the filling resin 330 is injected in a space in the cavity 160, and, at the same time, the second insulating resin layer 141 that covers the first insulating resin layer 131 and the component 310 is formed, so that the fourth layer 140 that is extended above the component 310 is formed. Accordingly, the component 310 is embedded in the build-up layer 100 and the component 310 is incorporated in the substrate.

At the stage at which the filling resin 330 is injected and the fourth layer 140 is formed, the filler-rich layer adheres to the second insulating resin layer 141 that is laminated on the filler-rich layer, so that adhesion strength between the second insulating resin layer 141 and the first insulating resin layer 131 is enhanced. In the filler-rich layer, in a plan view of the substrate, the occupancy rate of the filler in the first surface 132 is higher than the occupancy rate of the filler in the second surface 133. Therefore, by using the filler-rich layer as a film on the first surface 132, adhesion strength between resin layers in the first surface 132 dramatically increases as compared to adhesion strength between resin layers in the second surface 133. As a result, it is possible to maintain and enhance adhesion between the first insulating resin layer 131 of the third layer 130 and the second insulating resin layer 141 of the fourth layer 140 that are adjacent to each other in the build-up layer 100. Consequently, the first insulating resin layer 131 and the second insulating resin layer 141 are less likely to be delaminated, so that it is possible to prevent a plating layer from being formed between resin and prevent occurrence of a short circuit between wires.

Furthermore, after the component 310 is mounted, it is possible to add a process that may reduce adhesion between the first insulating resin layer 131 and the second insulating resin layer 141 before lamination of the fourth layer 140. For example, even when thermal treatment or chemical treatment that may cause a functional group of the first surface 132 of the first insulating resin layer 131 to disappear, it is possible to ensure stable adhesion strength between the first insulating resin layer 131 and the second insulating resin layer 141 by the filler-rich layer that is subsequently formed. Therefore, as a material of the first insulating resin layer 131 and the second insulating resin layer 141, for example, the same kind of resin, such as epoxy resin, may be used, but it is possible to ensure stable adhesion strength even with use of different kinds of resin.

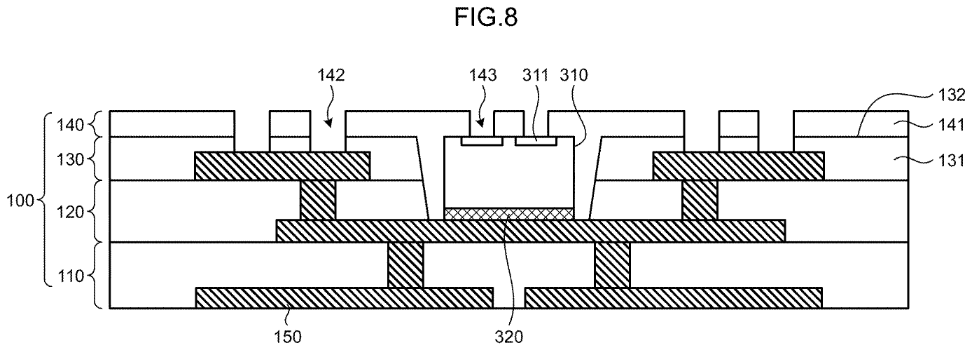

After the fourth layer 140 is formed by injecting filling resin 330 in the cavity 160 and, the resin is thermally cured. Further, vias for connecting the wiring layer 150 of the third layer 130, the electrode pad 311 of the component 310, and wires on the surface of the substrate are formed (Step S108). Specifically, as illustrated in FIG. 8 for example, a via 142 that is connected from the surface of the build-up layer 100 to the wiring layer 150 of the third layer 130 and a via 143 that is connected from the surface of the build-up layer 100 to the electrode pad 311 of the component 310 are formed by, for example, laser processing. The via 142 is a through hole that penetrates through the second insulating resin layer 141 and the first insulating resin layer 131. The via 142 is a recessed portion whose side surface is one surface in which an inner surface of the second insulating resin layer 141 and an inner surface of the first insulating resin layer 131 are continued and whose bottom surface is one surface of the wiring layer 150 of the build-up layer 100 (the third layer 130) different from the one surface of the wiring layer 150 in the cavity 160. In other words, the first insulating resin layer 131 and the second insulating resin layer 141 adhere to each other, and the inner surface of the first insulating resin layer 131 and the inner surface of the second insulating resin layer 141 are seamlessly continued. The via 143 is a through hole that penetrates through the second insulating resin layer 141, and is a recessed portion whose side surface is the inner surface of the second insulating resin layer 141 and whose bottom surface is one surface of the electrode pad 311.

Each of the vias 142 and 143 has an inverted truncated cone shape closer to a cylinder, and therefore, has a largest diameter on the surface of the build-up layer 100 and a smallest diameter at the bottom of the via. An upper surface of the wiring layer 150 of the third layer 130 is flat, and therefore, a depth and a diameter of the via bottom of the via 142 are constant independently of the position of the via 142. With this configuration, it is possible to improve connection reliability between the wiring layer 150 of the third layer 130 and the via 142. Further, an upper surface of the component 310 is flat, and therefore, a depth and a diameter of the via bottom of the via 143 are constant independently of the position of the via 143. With this configuration, an area of the via bottom that comes into contact with the electrode of the component 310 becomes constant. Consequently, it is possible to improve connection reliability between the electrode pad 311 of the component 310 and the via 143.

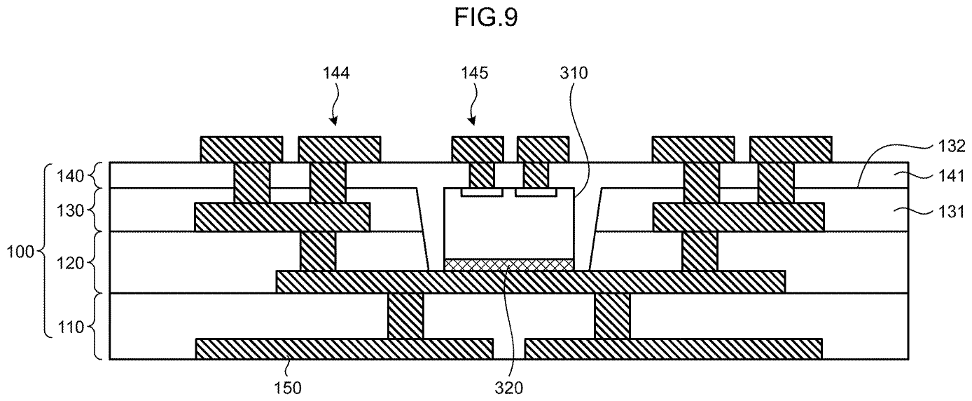

Furthermore, desmear treatment for removing a residue of the second insulating resin layer 141 and the first insulating resin layer 131 generated at the time of processing the vias is performed, in an electroless copper plating wiring process, wiring is formed on the surface of the substrate at the positions at which the vias 142 and 143 are formed (Step S109). Specifically, as illustrated in FIG. 9 for example, wiring 144 is formed at the position of the via 142, and wiring 145 is formed at the position of the via 143. The wiring 144 and 145 are formed by, for example, a Semi Additive Process (SAP). In the SAP, for example, exposure and developing of dry film resist are performed, however, in the present embodiment, it is possible to ensure good accuracy of exposure and developing because the surface of the build-up layer 100 is flat.

The wiring 144 is connected to the wiring layer 150 of the third layer 130 via the via 142, and the wiring 145 is connected to the electrode pad 311 of the component 310 via the via 143. In the present embodiment, with the aid of the filler-rich layer of the first surface 132, adhesion between the second insulating resin layer 141 and the first insulating resin layer 131 is improved. Therefore, the second insulating resin layer 141 and the first insulating resin layer 131 are less likely to be delaminated, so that it is possible to prevent occurrence of a short circuit of the wiring layer.

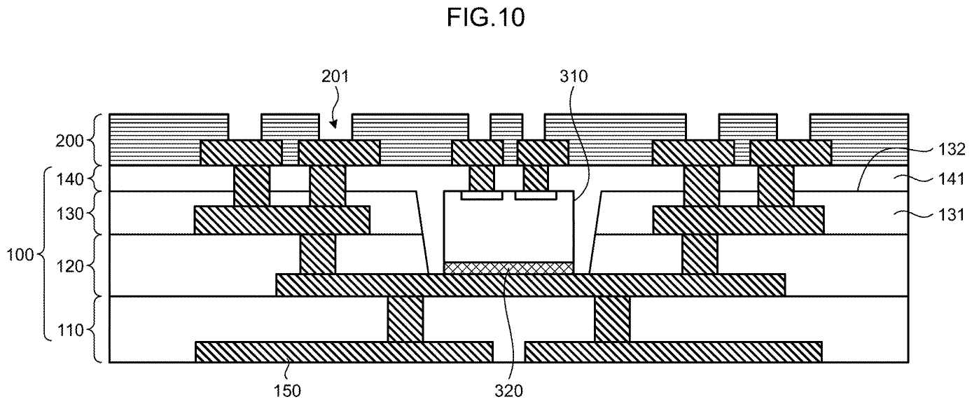

The wiring 144 and 145 on the surface of the substrate are, by formation of the solder resist layer 200 (Step S110), covered. The solder resist layer 200 is formed by film formation by performing pattern printing of insulating resin. Further, at positions corresponding to the wiring 144 and 145 on the surface of the substrate, as illustrated in FIG. 10 for example, openings 201 are arranged in the solder resist layer 200. The openings 201 are formed by using, for example, photolithography, laser, or the like. At the positions of the openings 201, an external component, such as a semiconductor chip, is disposed, for example.

Then, the bumps 210 are formed in the openings 201 by plating, a solder ball, or the like (Step S111). The bumps 210 serve as connection points between the wiring 144 and 145 on the surface of the substrate and an external component.

As described above, according to the component embedded substrate manufacturing method of the present embodiment, the build-up layer 100 is formed that contains filler and includes the first insulating resin layer 131, which includes the first surface 132 and the second surface 133 located opposite to the first surface 132, and the wiring layer 150. Further, the cavity 160 is formed by cutting the build-up layer 100 to one surface of the wiring layer 150, and the component 310 is disposed on the surface of the wiring layer 150 in the cavity 160. Furthermore, by plasma treatment, the filler-rich layer in which the occupancy rate of the filler in the first surface 132 is higher than the occupancy rate of the filler in the second surface 133 is formed on the first surface 132. Moreover, the second insulating resin layer 141 that is injected in the cavity 160 and covers the first insulating resin layer 131 and the component 310 is formed. Furthermore, the via 142 that penetrates through the second insulating resin layer 141 and the first insulating resin layer 131 and includes the surface of the wiring layer 150 of the third layer 130 as a bottom surface is formed.

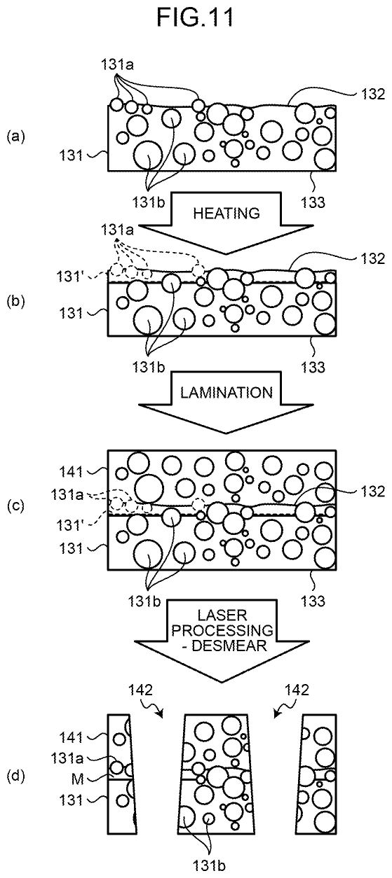

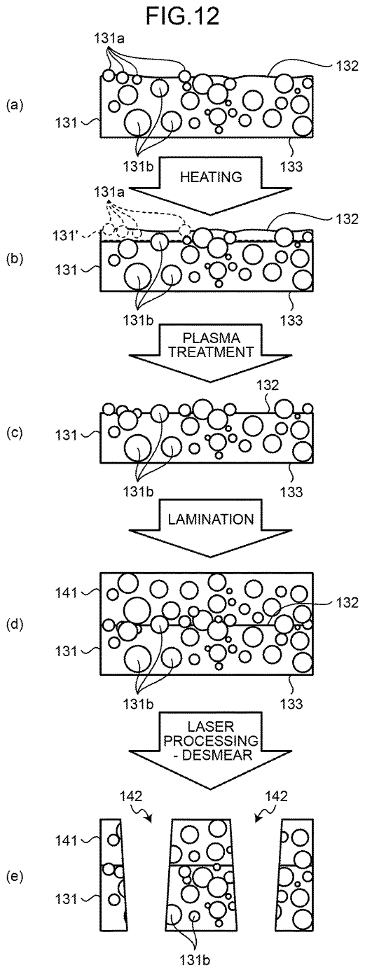

The filler-rich layer functions to improve adhesion between the first insulating resin layer 131 and the second insulating resin layer 141. Adhesion strength of the filler-rich layer will be described by comparing a reference example illustrated in FIG. 11 and FIG. 12 and an example of the component embedded substrate manufacturing method according to the present embodiment. FIG. 11 is a diagram illustrating an example of an interlayer between insulating resin layers according to the reference example. FIG. 12 is a diagram illustrating an example of an interlayer between insulating resin layers according to one embodiment.

In one embodiment, the first insulating resin layer 131 that is included in the third layer 130 contains, as illustrated in FIG. 11(a) and FIG. 12(a), filler 131a and filler 131b. The filler 131a is located at the position of the first surface 132 of the first insulating resin layer 131, and the filler 131b is located inside the first insulating resin layer 131 or at the second surface 133. The filler 131a and the filler 131b are distinguished from each other for convenience of explanation, and have the same adhesive strength at this time.

In the reference example and the present embodiment, a thermal treatment process that is one example of a process that prevents adhesion between resin layers was performed before laminating the second insulating resin layer 141 on the first insulating resin layer 131. In the thermal treatment process, the first insulating resin layer 131 was heated at temperature equal to or higher than 125 °C and equal to or lower than 150 °C.

As illustrated in FIG. 11(b) and FIG. 12(b), in the thermal treatment, the filler 131a that is located at the first surface 132 of the first insulating resin layer 131 was affected by heat and a functional group disappeared. Specifically, the filler 131a that is located at the first surface 132 reacted with oxygen or water in air and oxidized, so that reaction sensitivity of the functional group was reduced and reactivity of the functional group was lowered. Accordingly, a film 131′ in which the functional group disappeared was generated on the first surface 132. Therefore, in the reference example, as illustrated in FIG. 11(c), when the second insulating resin layer 141 was laminated, the film 131′ on the first surface 132 reduced adhesion strength at an interface between the first insulating resin layer 131 and the second insulating resin layer 141, so that poor adhesion occurred. Consequently, the first insulating resin layer 131 and the second insulating resin layer 141 were delaminated from each other, and therefore, in an electroless copper plating wiring process after formation of vias by laser processing and desmear treatment, plating was deposited between the resin layers. As a result, a plating layer M was formed between the resin layers as illustrated in FIG. 11(d). The plating layer M causes a short circuit to occur between adjacent wiring layers.

In contrast, in the present embodiment, a plasma treatment process was performed after the thermal treatment process. Specifically, in the present embodiment, the film 131′ in which the reactivity of the functional group was lowered as illustrated in FIG. 12(b) due to the thermal treatment was ashed by plasma that was generated from a CF₄ gas in a subsequent plasma treatment process. Consequently, as illustrated in FIG. 12(c), the film 131′ in which the reactivity of the functional group was lowered was removed, so that the first surface 132 was covered by the filler-rich layer from which the filler 131b was exposed. The filler-rich layer may be an altered layer of the first insulating resin layer 131 in which the filler 131b is exposed from the first surface 132 by plasma ashing. The filler 131b was not affected by heat, and therefore, the functional group of the filler 131b did not disappear. Thus, through the plasma treatment, the first surface 132 of the first insulating resin layer 131 entered a state in which adhesion strength is increased by the filler-rich layer from which a large amount of the filler 131b with high reactivity was exposed.

Therefore, as illustrated in FIG. 12(d), the filler-rich layer maintains and enhances the adhesion strength at the interface between the first insulating resin layer 131 and the second insulating resin layer 141 when the second insulating resin layer 141 is laminated on the first insulating resin layer 131. Further, the surface of the filler 131b is subjected to processing by a silane coupling agent that enhances adhesion to resin. Therefore, in the filler-rich layer, by causing the filler 131b to be exposed, it is possible to enhance the adhesion strength at the interface between the first insulating resin layer 131 and the second insulating resin layer 141.

Thus, as illustrated in FIG. 12(e), the second insulating resin layer 141 and the first insulating resin layer 131 firmly adhere to each other, and the via 142 has a side surface in which the inner surface of the second insulating resin layer 141 and the inner surface of the first insulating resin layer 131 are continued. With this configuration, in an electroless copper plating wiring process after the desmear treatment, the adhesion strength between the resin layers was maintained and a short circuit did not occur between the wiring layers.

Meanwhile, in the present embodiment, as a surrounding structure of the filler-rich layer, the wiring layer is not present on the second insulating resin layer 141 that is adjacent to the first surface 132 of the first insulating resin layer 131 at the time of embedding the component 310. If the wiring layer of the second insulating resin layer 141 is present on the first surface 132 that is covered by the filler-rich layer, adhesion between the wiring layer and the filler is reduced, so that wiring short or wiring floating may occur in the wiring layer of the second insulating resin layer 141.

However, the wiring layer is not present on the surface that is adjacent to the first surface 132 of the second insulating resin layer 141, and therefore, even when the filler-rich layer is formed in the plasma treatment process, wiring short or wiring floating does not occur in the second insulating resin layer 141, so that wiring failure is less likely to occur. As a result, the filler-rich layer that is formed on the first surface 132 of the first insulating resin layer 131 dramatically improves adhesion between the second insulating resin layer 141 and the first insulating resin layer 131, and poor adhesion to the wiring layer is less likely to occur.

In the method illustrated in FIG. 12, the example has been described in which plasma treatment is performed after thermal treatment, but embodiments are not limited to this example. For example, when chemical treatment or treatment corresponding to a type or property of the first insulating resin layer 131 is performed, and the functional group of the first surface 132 of the first insulating resin layer 131 disappears, it is effective to perform plasma treatment after the treatment, such as the chemical treatment. In other words, it may be possible to add a process of causing the filler of the first surface 132 to disappear before forming the filler-rich layer. With this configuration, by forming the filler-rich layer after the process of causing the filler to disappear, it is possible to recover the adhesion strength between the second insulating resin layer 141 and the first insulating resin layer 131, so that it is possible to prevent occurrence of a short circuit between wires.

In the filler-rich layer, in a plan view of the substrate, the occupancy rate of the filler in the first surface 132 may be equal to or higher than 50%. With this configuration, the filler-rich layer is able to reliably increase adhesion between the second insulating resin layer 141 and the first insulating resin layer 131. Further, in the filler-rich layer, in a plan view of the substrate, the occupancy rate of the filler in the first surface 132 may be equal to or higher than 80%. With this configuration, the filler-rich layer is able to further enhance the adhesion strength between the second insulating resin layer 141 and the first insulating resin layer 131.

The component embedded substrate as described above includes the build-up layer 100 that contains filler and includes the first insulating resin layer 131, which contains filler and includes the first surface 132 and the second surface 133 located opposite to the first surface 132, and the wiring layer 150; the cavity 160 that is formed by cutting the build-up layer 100 to one surface of the wiring layer 150; the component 310 that is located on one surface of the wiring layer 150 in the cavity 160; the filler-rich layer that is formed on the first surface 132 and configured such that the occupancy rate of the filler in the first surface 132 is higher than the occupancy rate of the filler in the second surface 133; the second insulating resin layer 141 that is injected in the cavity 160 and covers the first insulating resin layer 131 and the component 310; and the via 142 that is formed so as to penetrate through the second insulating resin layer 141 and the first insulating resin layer 131 and has a one surface of the wiring layer 150 of the third layer 130 as a bottom surface.

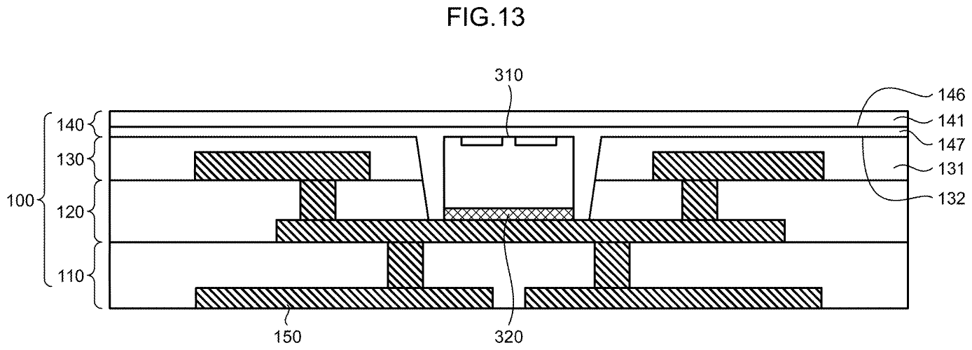

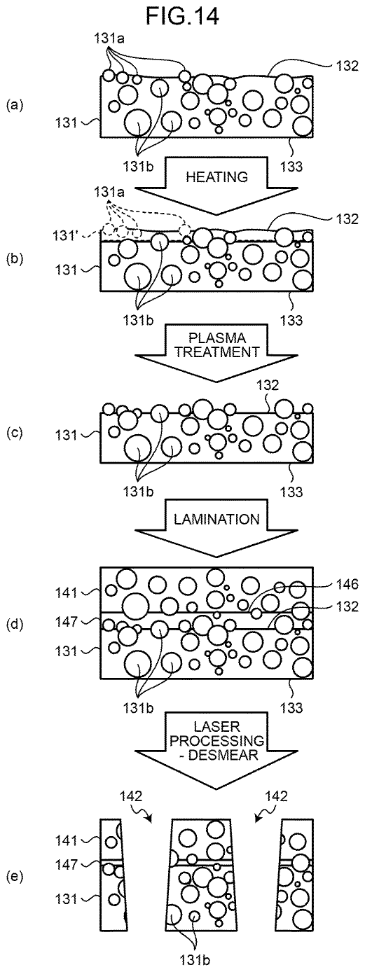

Furthermore, the component embedded substrate may include an adhesion enhancement layer between the second insulating resin layer 141 and the first insulating resin layer 131. FIG. 13 is a diagram illustrating another specific example of a component embedding process. FIG. 14 is a diagram illustrating an example of an interlayer between insulating resin layers in the other specific example of the component embedding process. In the other specific example of the component embedding process, a process as described below is performed in the component embedding process at Step S107 in FIG. 2, and the same processes as those in FIG. 2 are performed at Steps other than Step S107 in FIG. 2.

Even in the other specific example of the component embedding process, the component 310 is embedded by laminating the fourth layer 140 on the third layer 130. Further, the adhesion enhancement layer is provided between the second insulating resin layer 141 of the fourth layer 140 and the first insulating resin layer 131 of the third layer 130. Specifically, as illustrated in FIG. 13 for example, filling resin is injected in a space in the cavity 160, and at the same time, the second insulating resin layer 141 is formed in an upper part via an adhesion enhancement layer 147 that covers the first surface 132 and the component 310. Specifically, the fourth layer 140 includes the adhesion enhancement layer 147 and the second insulating resin layer 141, and the second insulating resin layer 141 is laminated above the first insulating resin layer 131 via the adhesion enhancement layer 147. For example, the adhesion enhancement layer 147 is able to further enhance adhesion between a surface 146 that comes into contact with the second insulating resin layer 141 and the first surface 132 that comes into contact with the first insulating resin layer 131.

With this configuration, through the plasma treatment, the film 131′ in which the reactivity of the functional group is lowered is subjected to plasma ashing and the filler-rich layer is formed on the first surface 132 as illustrated in FIG. 14(c), and thereafter, the adhesion enhancement layer 147 and the second insulating resin layer 141 are laminated as illustrated in FIG. 14(d). The adhesion enhancement layer 147 is a layer in which the functional group that contributes to adhesion is increased as compared to the second insulating resin layer 141 in order to enhance adhesion strength, and therefore, allows the second insulating resin layer 141 and the first insulating resin layer 131 to more firmly bond together at interfaces. Accordingly, as illustrated in FIG. 14(e), the via 142 has a side surface in which the inner surface of the first insulating resin layer 131, an inner surface of the adhesion enhancement layer 147, and the inner surface of the second insulating resin layer 141 are continued. With this configuration, in the electroless copper plating wiring process after the desmear treatment, the adhesion enhancement layer 147 firmly maintains the adhesion strength between the resin layers, so that it is possible to prevent occurrence of a short circuit between the wiring layers.

Meanwhile, in the present embodiment, it is assumed that the wiring layer 150 that is located on the bottom surface of the cavity 160 is connected to the different wiring layer 150 by the via, but embodiments are not limited to this example. For example, the wiring layer 150 that is located on the bottom surface of the cavity 160 may be floated without being connected to the different wiring layer 150.

According to one aspect of the component embedded substrate manufacturing method and the component embedded substrate disclosed in the present application, it is possible to improve adhesion between insulating resin layers in which a component that is incorporated in a substrate is embedded.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An component embedded substrate comprising:
a build-up layer that contains filler and includes a first insulating resin layer, the first insulating layer including a first surface and a second surface located opposite to the first surface, and a wiring layer;
a cavity that is formed by cutting the build-up layer to one surface of the wiring layer;
an electrical component that is located on the one surface of the wiring layer in the cavity;
a filler-rich layer that is formed on the first surface and configured such that an occupancy rate of filler in the first surface is higher than an occupancy rate of filler in the second surface;
a second insulating resin layer that is injected in the cavity and convers the first insulating resin layer and the electrical component; and
a via that is formed so as to penetrate through the second insulating resin layer and the first insulating resin layer and has a bottom surface that is one surface of a different wiring layer of the build-up layer from the one surface of the wiring layer in the cavity.

2. The component embedded substrate according to claim 1, further comprising:
an adhesion enhancement layer between the second insulating resin layer and the first insulating resin layer.

3. The component embedded substrate according to claim 2, wherein a wiring layer is not formed on the first surface of the first insulating resin layer.

4. An component embedded substrate manufacturing process comprising:
forming a build-up layer that contains filler and includes a first insulating resin layer, the first insulating layer including a first surface and a second surface located opposite to the first surface, and a wiring layer;
forming a cavity by cutting the build-up layer to one surface of the wiring layer;
disposing an electrical component on the one surface of the wiring layer in the cavity;
forming, on the first surface, a filler-rich layer that is configured such that an occupancy rate of filler in the first surface is higher than an occupancy rate of filler in the second surface, by plasma treatment;
forming a second insulating resin layer that is injected in the cavity and convers the first insulating resin layer and the electrical component; and
forming a via that penetrates through the second insulating resin layer and the first insulating resin layer and that has a bottom surface formed of one surface of a different wiring layer of the build-up layer from the one surface of the wiring layer in the cavity.

5. The component embedded substrate manufacturing method according to claim 4, wherein the filler-rich layer is configured such that an occupancy rate of filler in the first surface is equal to or higher than 50% in a plan view.

6. The component embedded substrate manufacturing method according to claim 4, wherein the filler-rich layer is configured such that an occupancy rate of filler in the first surface is equal to or higher than 80% in a plan view.

7. The component embedded substrate manufacturing method according to claim 4, wherein the via includes a recessed portion whose side surface is one surface in which an inner surface of the second insulating resin layer and an inner surface of the first insulating resin layer are continued and whose bottom surface is the one surface of a wiring layer of the build-up layer.

8. The component embedded substrate manufacturing method according to claim 4, wherein the second insulating resin layer is laminated on the first insulating resin layer via an adhesion enhancement layer.

9. The component embedded substrate manufacturing method according to claim 4, wherein the plasma treatment includes generating plasma from a gas containing carbon and fluorine and performing ashing by the plasma on the first insulating resin layer.

10. The component embedded substrate manufacturing method according to claim 4, further comprising:
causing the filler in the first surface to disappear before forming the filler-rich layer.
